(19) United States
(12) Patent Application Publication
(10) Pub. No.: US 2024/0380171 A1
(43) Pub. Date: Nov. 14, 2024

(54) OPTICAL MODULE, OPTICAL TRANSCEIVER, AND METHOD OF CONTROLLING INTENSITY OF LIGHT

(71) Applicant: NEC Corporation, Tokyo (JP)

(72) Inventors: Kimiyoshi FUKATSU, Tokyo (JP); Taro KANEKO, Tokyo (JP)

(73) Assignee: NEC Corporation, Tokyo (JP)

(21) Appl. No.: 18/645,669

(22) Filed: Apr. 25, 2024

(30) Foreign Application Priority Data
May 12, 2023 (JP) 2023-079239

(51) Int. Cl. H01S 3/10; H01S 3/067

(52) U.S. Cl. CPC H01S 3/10015; H01S 3/06783

(57) ABSTRACT

An optical amplifier modulates first light with a first modulation signal having a first frequency, and modulates second light with a second modulation signal having a second frequency. A splitter splits the first light and the second light. A light reception unit outputs an electric signal indicating intensity of light acquired by adding the received first light and the received second light. An intensity detection unit extracts a first component having the first frequency and a second component having the second frequency included in the electric signal, and detects amplitude of each of the first and second components. An amplification control unit monitors intensity of the first light based on amplitude of the first component and intensity of the second light based on amplitude of the second component, and controls amplification of each of the first light and the second light in the optical amplifier.

### INCORPORATION BY REFERENCE

This application is based upon and claims the benefit of priority from Japanese patent application No. 2023-79239, filed on May 12, 2023, the disclosure of which is incorporated herein in its entirety by reference.

### TECHNICAL FIELD

The present disclosure relates to an optical module, an optical transceiver, and a method of controlling intensity of light.

### BACKGROUND ART

In a digital coherent technique applied to optical communication, a wavelength tunable light source such as an integrable tunable laser assembly (ITLA) is mounted as a light source in an optical communication apparatus. Light being output from the ITLA is split toward a reception-side apparatus and a transmission-side apparatus. The transmission-side apparatus transmits an optical signal acquired by modulating input light in response to a data signal. The reception-side apparatus demodulates an optical signal being received from another communication apparatus or the like to an intensity signal by causing the optical signal to interfere with light to be input. In this case, a wavelength of light to be input to the transmission-side apparatus and a wavelength of light to be input to the reception-side apparatus are the same wavelength.

In such a configuration, processing such as stabilization (Japanese Unexamined Patent Application Publication No. 2008-244270) and amplification (Japanese Unexamined Patent Application Publication No. 2007-193209) of light to be supplied to the transmission-side apparatus and the reception-side apparatus, and modulation (Japanese Unexamined Patent Application Publication No. 2001-133824) of light by various modulation methods is performed.

### SUMMARY

In this case, in general, it is possible to handle two wavelengths by using two wavelength tunable light sources having different wavelengths of output light from each other. In this case, it is required to keep intensity of light of each of the two wavelengths constant. When two different light sources are mounted, light intensity can be kept constant by the same method so far, however, the light source is strongly required to be small in size and low in power consumption, and it is required to integrate the two light sources. In this case, in a path guiding light from a light source for outputting light of two wavelengths to a transmission side and a reception side, a place where light of two wavelengths passes through the same path occurs. Thus, it becomes difficult to individually monitor intensity of light of two wavelengths.

The present disclosure has been made in view of the above-described circumstances, and an object of the present disclosure is to monitor intensity of light of two wavelengths being guided by the same path with a simple configuration.

An aspect of the present disclosure is an optical module including: an optical amplifier configured to modulate first light having a first wavelength with a first modulation signal having a first frequency and amplify the first light, and modulate second light having a second wavelength different from the first wavelength with a second modulation signal having a second frequency different from the first frequency and amplify the second light; a splitter configured to split the first light and the second light being output from the optical amplifier; a light reception unit configured to receive the first light and the second light being split by the splitter, and output an electric signal indicating intensity of light acquired by adding the received first light and the received second light; an intensity detection unit configured to extract a first component having the first frequency being included in the electric signal and a second component having the second frequency being included in the electric signal, and detect amplitude of the first component and amplitude of the second component; and an amplification control unit configured to monitor intensity of the first light, based on amplitude of the first component, monitor intensity of the second light, based on amplitude of the second component, and control amplification of each of the first light and the second light in the optical amplifier, based on a monitoring result.

An aspect of the present disclosure is an optical transceiver including: a receiver configured to receive a received first wavelength multiplexed optical signal by interfering with first light having a first wavelength, and output a data signal acquired by demodulating the received signal; a transmitter configured to modulate second light having a second wavelength different from the first wavelength in response to the data signal, and multiplex the modulated optical signal into a second wavelength multiplexed optical signal and output the multiplexed signal; a signal processing unit configured to transfer the data signal being output from the receiver to the transmitter; and an optical module configured to output the first light and the second light, in which the optical module includes an optical amplifier configured to modulate the first light with a first modulation signal having a first frequency and amplify the first light, and modulate the second light with a second modulation signal having a second frequency different from the first frequency and amplify the second light, a splitter configured to split the first light and the second light being output from the optical amplifier, a light reception unit configured to receive the first light and the second light being split by the splitter, and output an electric signal indicating intensity of light acquired by adding the received first light and the received second light, an intensity detection unit configured to extract a first component having the first frequency being included in the electrical signal and a second component having the second frequency being included in the electric signal, and detect amplitude of the first component and amplitude of the second component, and an amplification control unit configured to monitor intensity of the first light, based on amplitude of the first component, monitor intensity of the second light, based on amplitude of the second component, and control amplification of each of the first light and the second light in the optical amplifier, based on a monitoring result.

An aspect of the present disclosure is a method of controlling intensity of light, including: modulating first light having a first wavelength with a first modulation signal having a first frequency and amplifying the first light, and modulating second light having a second wavelength different from the first wavelength with a second modulation signal having a second frequency different from the first frequency and amplifying the second light; splitting the first light and the second light being modulated and amplified; receiving the first light and the second light being split, and outputting an electric signal indicating intensity of light acquired by adding the received first light and the received second light; extracting a first component having the first frequency being included in the electric signal and a second component having the second frequency being included in the electric signal, and detecting amplitude of the first component and amplitude of the second component; and monitoring intensity of the first light, based on amplitude of the first component, monitoring intensity of the second light, based on amplitude of the second component, and controlling amplification of each of the first light and the second light, based on a monitoring result.

### BRIEF DESCRIPTION OF DRAWINGS

The above and other aspects, features and advantages of the present disclosure will become more apparent from the following description of certain exemplary embodiments when taken in conjunction with the accompanying drawings, in which:

FIG. 1 is a diagram schematically illustrating a configuration of an optical transceiver using an optical module according to a first example embodiment;

FIG. 2 is a diagram schematically illustrating a configuration of the optical module according to the first example embodiment;

FIG. 3 is a diagram illustrating the configuration of the optical module according to the first example embodiment in more detail;

FIG. 4 is a diagram illustrating intensity of a detection signal, and a signal component of first light and a signal component of second light included in the detection signal;

FIG. 5 is a flowchart of feedback control in the first example embodiment;

FIG. 6 is a diagram schematically illustrating a configuration of an optical module according to a second example embodiment; and

FIG. 7 is a flowchart of feedforward control in the second example embodiment.

### EXAMPLE EMBODIMENT

Hereinafter, example embodiments of the present disclosure will be described with reference to the drawings. In the drawings, the same elements are denoted by the same reference signs, and redundant description is omitted as necessary.

### First Example Embodiment

An optical module according to a first example embodiment will be described. The optical module according to the first example embodiment is configured as a wavelength tunable light source module that outputs first light L1 and second light L2 having wavelengths different from each other.

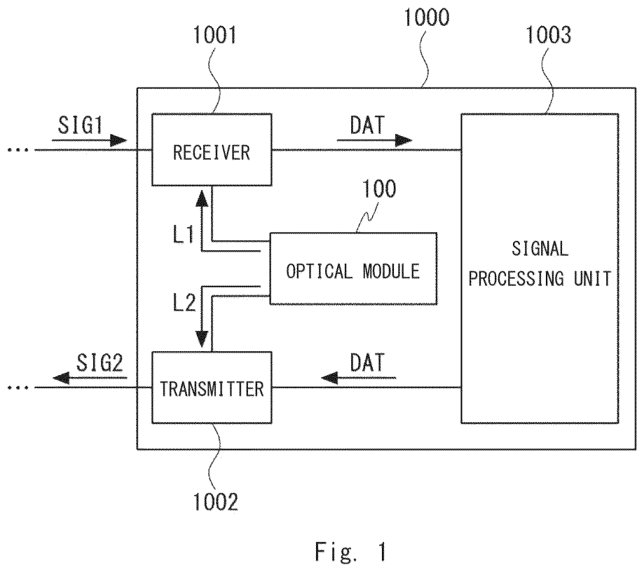

FIG. 1 schematically illustrates a configuration of an optical transceiver 1000 using an optical module according to the first example embodiment. The optical transceiver 1000 includes a receiver 1001, a transmitter 1002, a signal processing unit 1003, and an optical module 100 according to the present example embodiment.

The optical module 100 outputs the first light L1 and the second light L2 having different wavelengths from each other to the receiver 1001 and the transmitter 1002, respectively. Hereinafter, a wavelength of the first light L1 is represented by λ1. A wavelength of the second light L2 is represented by λ2.

The receiver 1001 receives a wavelength multiplexed optical signal SIG1 acquired by wavelength multiplexing an optical signal having the wavelength λ1 from another optical transceiver or the like. The receiver 1001 selectively receives the optical signal having the wavelength λ1 by causing the first light L1 received from the optical module 100 to interfere with the wavelength multiplexed optical signal SIG1. Then, the receiver 1001 outputs a data signal DAT acquired by demodulating the received optical signal having the wavelength λ1 to the signal processing unit 1003.

The signal processing unit 1003 transfers the received data signal DAT to the transmitter 1002. The signal processing unit 1003 is configured as a digital signal processor (DSP) for digital coherence. The DSP has a function of outputting the received signal as it is, so-called loopback. Thus, the received data signal DAT can be transferred to the transmitter 1002 by using loopback included in the signal processing unit 1003. Further, for example, the signal processing unit 1003 may be connected to a host apparatus via a not-illustrated electrical connector, the signal processing unit 1003 may transfer an electric signal A from the host apparatus to the transmitter 1002, and the signal processing unit 1003 may transfer an electric signal B from the receiver 1001 to the host apparatus.

The transmitter 1002 modulates the second light L2 received from the optical module 100, based on the data signal DAT, and wavelength multiplexes the modulated optical signal to a wavelength multiplexed optical signal SIG2. Then, the transmitter 1002 outputs the wavelength multiplexed optical signal SIG2 to an optical transceiver or the like of a transmission destination.

As described above, the optical transceiver 1000 can convert the received optical signal having the wavelength λ1 into an optical signal having the wavelength λ2.

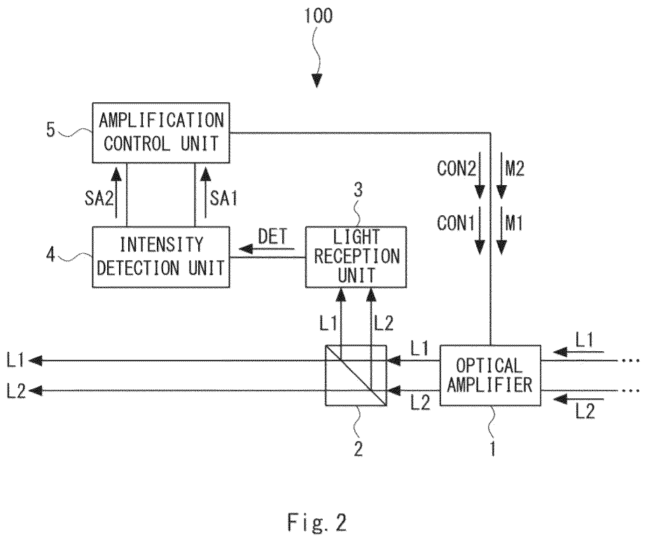

Next, the optical module 100 will be described. FIG. 2 schematically illustrates a configuration of the optical module 100 according to the first example embodiment. The optical module 100 includes an optical amplifier 1, an optical splitter 2, a light reception unit 3, an intensity detection unit 4, and an amplification control unit 5.

The optical amplifier 1 amplifies each of input first light L1 and input second light L2. Further, the optical amplifier 1 modulates each of the first light L1 and the second light L2 in response to modulation signals M1 and M2 supplied from the amplification control unit 5. Then, the optical amplifier 1 outputs the amplified and modulated first light L1 and second light L2 to the optical splitter 2. Note that, the modulation signal M1 is also referred to as a first modulation signal. The modulation signal M2 is also referred to as a second modulation signal.

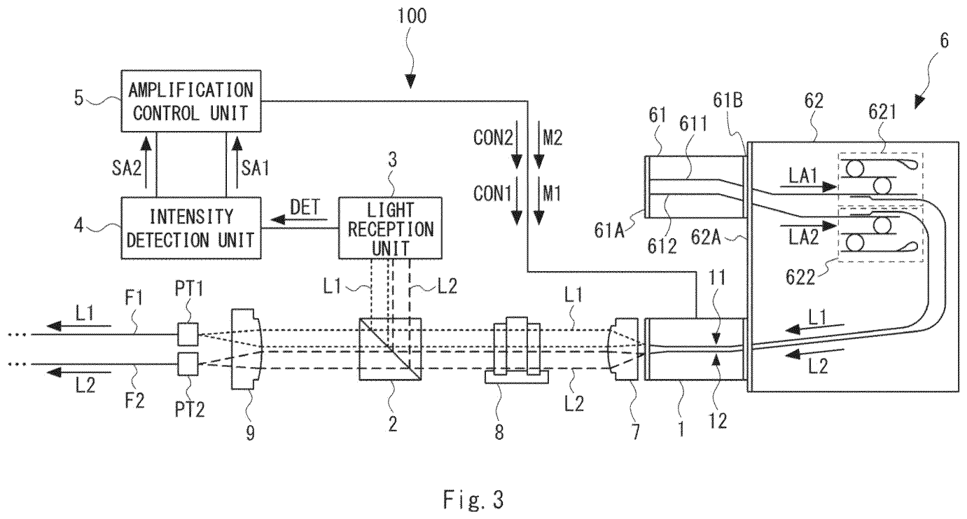

The optical amplifier 1 will be described in more detail. FIG. 3 illustrates the configuration of the optical module 100 according to the first example embodiment in more detail. In FIG. 3, in order to illustrate propagation paths of each of the first light L1 and the second light L2, a spread of a beam of the first light L1 and second light L2 is displayed.

The optical amplifier 1 includes a first optical amplification unit 11 that amplifies and modulates the first light L1, and a second optical amplification unit 12 that amplifies and modulates the second light L2.

The first optical amplification unit 11 amplifies the first light L1 incident from a light source 6 with an amplification factor associated to a control signal CON1 input from the amplification control unit 5.

Further, the first optical amplification unit 11 modulates the first light L1 in response to the modulation signal M1 input from the amplification control unit 5. In this example, the modulation signal M1 is a sinusoidal signal having a frequency f1. The first light L1 being amplified and modulated by the first optical amplification unit 11 is output to the optical splitter 2 as light whose intensity varies periodically at the frequency f1. Note that, the frequency f1 is also referred to as a first frequency.

Intensity P1 of the first light L1 output from the first optical amplification unit 11 is expressed by the following equation as a function of a current I1 applied to the first optical amplification unit 11.

$$P 1 ( I 1 ) = F 1 ( I 1 ( 1 + r sin ( 2 π f 1 t ) ) ) \qquad [ 1 ]$$

In the equation [1], r is amplitude of a modulation component to be superimposed, and F1 is a function indicating a relationship between the intensity of the first light L1 and the current I1. The function depends on a characteristic of an optical amplifier, and is derived in advance.

The second optical amplification unit 12 amplifies the second light L2 incident from the light source 6 with an amplification factor associated to a control signal CON2 input from the amplification control unit 5.

Further, the second optical amplification unit 12 modulates the second light L2 in response to the modulation signal M2 input from the amplification control unit 5. In this example, the modulation signal M2 is a sinusoidal signal having a frequency f2. The second light L2 being amplified and modulated by the second optical amplification unit 12 is output to the optical splitter 2 as light whose intensity varies periodically at the frequency f2. Note that, the frequency f2 is also referred to as a second frequency.

Intensity P2 of the second light L2 output from the second optical amplification unit 12 is expressed by the following equation as a function of a current I2 applied to the second optical amplification unit 12.

$$P 2 ( I 2 ) = F 2 ( I 2 ( 1 + r sin ( 2 π f 2 t ) ) ) \qquad [ 2 ]$$

In the equation [2], as in the equation [1], r is the amplitude of the modulation component to be superimposed, and F2 is a function indicating a relationship between the intensity of the second light L2 and the current I2. The function depends on a characteristic of an optical amplifier, and is derived in advance.

The optical splitter 2 splits the incident first light L1 into an output port PT1 and the light reception unit 3. Further, the optical splitter 2 splits the incident second light L2 into an output port PT2 and the light reception unit 3. Herein, a ratio of light reflected by the optical splitter 2 to the light reception unit 3 is denoted as γ, and a ratio of light transmitted through the optical splitter 2 and output to an outside of the optical module 100 is denoted as 1-γ.

Each of the output ports PT1 and PT2 is connected to another optical component by optical fibers F1 and F2, respectively. Thus, for example, the first light L1 is output to the receiver 1001, and the second light L2 is output to the transmitter 1002.

The light reception unit 3 receives the first light L1 and the second light L2 being split by the optical splitter 2. Then, the light reception unit 3 outputs a detection signal DET associated to intensity of light acquired by adding the first light L1 and the second light L2 to the intensity detection unit 4. The light reception unit 3 can be configured by, for example, a photodiode. In this case, the light reception unit 3 outputs a current signal indicating the intensity of the light acquired by adding the first light L1 and the second light L2 to the intensity detection unit 4 as the detection signal DET.

The intensity detection unit 4 performs predetermined signal processing on the detection signal DET, and thereby detects the intensity of each of the first light L1 and the second light L2. As described above, the detection signal DET is a signal in which a component of the intensity of the first light L1 periodically varying at the frequency f1 and a component of the intensity of the second light L2 periodically varying at the frequency f2 are superimposed on each other.

Therefore, signal intensity of the detection signal DET is expressed by the following equation.

$$DET = η γ ( P 1 + P 2 ) \qquad [ 3 ]$$

In the equation [3], n is conversion efficiency of the light reception unit 3. γ is a splitting ratio of light in the optical splitter 2 as described above.

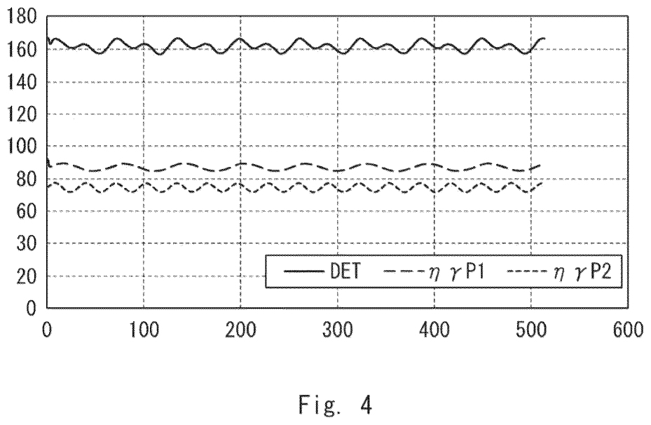

FIG. 4 illustrates the intensity of the detection signal DET, and a signal component of the first light L1 and a signal component of the second light L2 included in the detection signal DET. In this way, the detection signal DET is a signal acquired by adding a signal component ηγP1 of the first light L1 and a signal component ηγP2 of the second light L2. Note that, each of the signal component of the first light L1 and the signal component of the second light L2 is also referred to as a first component and a second component, respectively.

Therefore, by passing the detection signal DET through a frequency filter that passes only the signal component having the frequency f1, the intensity detection unit 4 can extract the signal component having the frequency f1 being a variation component of the first light L1 from the detection signal DET. Then, the intensity detection unit 4 outputs an amplitude signal SA1 indicating amplitude A1 of the variation component of the first light L1 to the amplification control unit 5.

Similarly, by passing the detection signal DET through the frequency filter that passes only the signal component having the frequency f2, the intensity detection unit 4 can extract the signal component having the frequency f2 being a variation component of the second light L2 from the detection signal DET. Then, the intensity detection unit 4 outputs an amplitude signal SA2 indicating amplitude A2 of the variation component of the second light L2 to the amplification control unit 5.

The amplification control unit 5 outputs the above-described modulation signals M1 and M2 to the first optical amplification unit 11 and the second optical amplification unit 12 of the optical amplifier 1, respectively.

Further, the amplification control unit 5 controls the first optical amplification unit 11 by using the control signal CON1 in such a way that amplitude of the variation component of the first light L1 becomes constant, based on the amplitude signal SA1. The first optical amplification unit 11 adjusts a value of the current I1 in response to the control signal CON1, and thereby can make the amplitude of the variation component of the first light L1 constant.

Similarly, the amplification control unit 5 controls the second optical amplification unit 12 by using the control signal CON2 in such a way that amplitude of the variation component of the second light L2 becomes constant, based on the amplitude signal SA2. The second optical amplification unit 12 adjusts a value of the current I2 in response to the control signal CON2, and thereby can make the amplitude of the variation component of the second light L2 constant.

Next, the light source 6 will be described. FIG. 3 illustrates a configuration example of the light source 6. The light source 6 is configured as a wavelength tunable light source being capable of outputting the first light L1 and the second light L2 having wavelengths different from each other. The light source 6 includes a laser element 61 and an external resonator 62.

In the laser element 61, a first stripe 611 and a second stripe 612 made of an active medium being arranged separately in parallel in a direction orthogonal to an extending direction are formed on the same substrate. Each of a high reflection film 61A and a non-reflection film 61B are formed on two end surfaces of the laser element 61, respectively. The laser element 61 emits light LA1 and light LA2 being a laser beam having different wavelengths from each other to the external resonator 62 from the end surface of the first stripe 611 and the second stripe 612 on which the non-reflection film 61B is formed. Each of paths of the light LA1 and the light LA2 illustrated in FIG. 3 indicates a trajectory of a beam center.

The external resonator 62 includes a first resonance unit 621 and a second resonance unit 622. Further, a non-reflection film 62A is formed on an end surface of the external resonator 62 where light is incident and emits. The first resonance unit 621 causes the light LA1 being incident from the laser element 61 to resonate between the end surface of the laser element 61 and a reflection means in the first resonance unit 621, and thereby emits the first light L1 being laser light having a first wavelength to the optical amplifier 1. The second resonance unit 622 causes the light LA2 being incident from the laser element 61 to resonate between the end surface of the laser element 61 and a reflection means in the second resonance unit 622, and thereby emits the second light L2 being laser light having a second wavelength to the optical amplifier 1.

Each of the first resonance unit 621 and the second resonance unit 622 may be configured as various resonators. Each of the first resonance unit 621 and the second resonance unit 622 may be configured as a resonator that selects a wavelength of resonating light by providing, for example, a wavelength filter including two ring waveguides. In this case, by providing a heater in the ring waveguide and changing a temperature of the ring resonator, a refractive index of the ring waveguide is adjusted, and thereby it is possible to control, to a desired wavelength, each of the first light L1 and the second light L2 resonating at the first resonance unit 621 and the second resonance unit 622.

In the first resonance unit 621 and the second resonance unit 622, an emission waveguide of each of the first light L1 and the second light L2 is inclined with respect to an emission end surface in order to further reduce a reflectance of the non-reflection film. Therefore, each of the first light L1 and the second light L2 is emitted in a direction inclined with respect to the emission end surface.

Further, as illustrated in FIG. 3, a first lens 7, an isolator 8, and a second lens 9 may be disposed in the optical module 100.

The first lens 7 and the isolator 8 are disposed between the optical amplifier 1 and the optical splitter 2. Each of the first light L1 and the second light L2 emitted from the optical amplifier 1 in different directions from each other is incident on the first lens 7 while being diffused. The first lens 7 converts the first light L1 and the second light L2 into light beams parallel to each other. The first light L1 and the second light L2 that become the parallel light beams pass through the isolator 8, and then are incident on the optical splitter 2. As a result, even when the first light L1 and the second light L2 are reflected after passing through the isolator 8 and incident on the isolator 8 as reflected light, the reflected light is blocked by the isolator 8. This makes it possible to prevent the reflected light from being incident on the optical amplifier 1 and the light source 6.

The second lens 9 is disposed on an output side of the optical splitter 2. The second lens 9 converges the first light L1 and the second light L2 being incident from the optical splitter 2, and emits the first light L1 and the second light L2 toward the output ports PT1 and PT2, respectively.

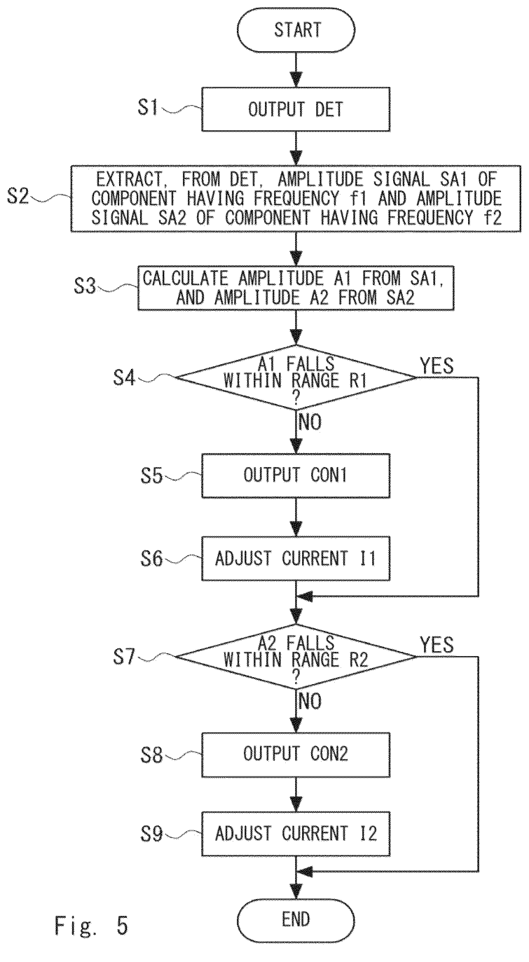

Next, feedback control of intensity of each of the first light L1 and the second light L2 will be described. FIG. 5 illustrates a flowchart of feedback control according to the first example embodiment.

### Step S1

The light reception unit 3 outputs the detection signal DET indicating intensity of light acquired by adding the first light L1 and the second light L2.

### Step S2

The intensity detection unit 4 performs frequency separation on the detection signal DET, and thereby acquires the amplitude signal SA1 for the first light L1 and the amplitude signal SA2 for the second light L2.

### Step S3

The intensity detection unit 4 calculates the amplitude A1 of the signal component having the frequency f1 of the first light L1 from the amplitude signal SA1. Further, the intensity detection unit 4 calculates the amplitude A2 of the signal component having the frequency f2 of the second light L2 from the amplitude signal SA2.

### Step S4

The amplification control unit 5 determines whether the amplitude A1 falls within a predetermined range R1. Note that, the predetermined range R1 is also referred to as a first range.

### Step S5

When the amplitude A1 does not fall within the predetermined range R1, the amplification control unit 5 outputs the control signal CON1 to the optical amplifier 1 in order to fall the amplitude A1 within the predetermined range R1.

The optical amplifier 1 adjusts the current I1 of the first optical amplification unit 11 in response to the control signal CON1.

### Step S7

The amplification control unit 5 determines whether the amplitude A2 falls within a predetermined range R2. Note that, the predetermined range R2 is also referred to as a second range.

### Step S8

When the amplitude A2 does not fall within the predetermined range R2, the amplification control unit 5 outputs the control signal CON2 to the optical amplifier 1 in order to fall the amplitude A2 within the predetermined range R2.

### Step S9

The optical amplifier 1 adjusts the current I2 of the second optical amplification unit 12 in response to the control signal CON2.

In FIG. 5, the processing of steps S7 to S9 is performed after the processing of steps S4 to S6, but this is merely an example. The processing of steps S4 to S6 may be performed after the processing of steps S7 to S9 is performed first, or the processing of steps S4 to S6 and the processing of steps S7 to S9 may be performed in parallel.

As a result, the optical module 100 can perform feedback control in such a way that the intensity of each of the first light L1 and the second light L2 becomes a desired value.

Note that, the intensity of each of the first light L1 and the second light L2 can be continuously controlled by regularly or intermittently performing the feedback control constituted of the above-described steps S1 to S9.

Therefore, according to the present configuration, intensity of each of the first light L1 and the second light L2 can be controlled with high accuracy by feedback control.

Note that, in a case of monitoring light having two wavelengths as in the present example embodiment, it is also conceivable to provide two pairs of a light reception unit and an intensity detection unit, and monitor each piece of light having the two wavelengths by the two pairs. However, in this case, the number of components increases, and thus it leads to an increase in a size of an optical module and an increase in a manufacturing cost of the optical module.

In contrast, the optical module 100 has a simple configuration for monitoring intensity of each of the first light L1 and the second light L2, based on light received by the single light reception unit 3. As a result, the optical module can be decreased in a size, and the manufacturing cost can be reduced.

### Second Example Embodiment

In the first example embodiment, feedback control based on a monitoring result of intensity of each of first light L1 and second light L2 has been described. Meanwhile, when an optical module is operated, first, feedforward control for performing initial setting of the intensity of each of the first light L1 and the second light L2 is performed. Then, in the present example embodiment, the feedforward control of the intensity of each of the first light L1 and the second light L2 will be described.

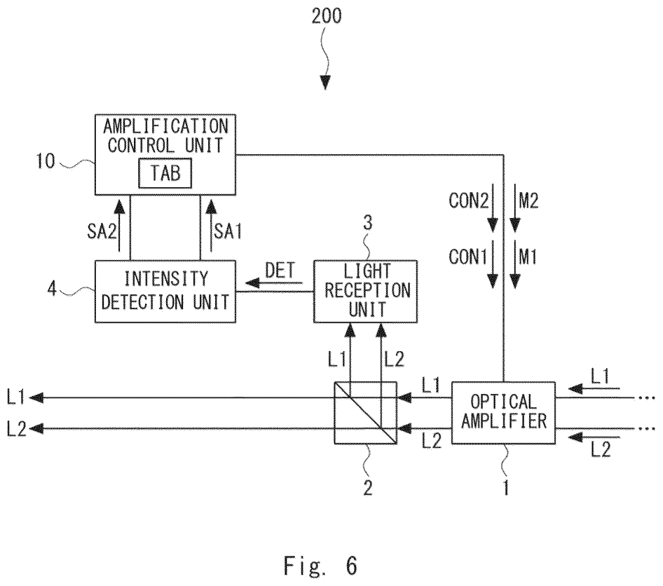

FIG. 6 schematically illustrates a configuration of an optical module 200 according to a second example embodiment. The optical module 200 has a configuration in which the amplification control unit 5 of the optical module 100 is replaced with an amplification control unit 10.

When the feedforward control of the intensity of each of the first light L1 and the second light L2 is performed, the amplification control unit 10 outputs control signals CON1 and CON2 associated to target intensity to a first optical amplification unit 11 and a second optical amplification unit 12, respectively. For this purpose, a correlation between a value of the control signal CON1, for example, a voltage, and the intensity of the first light L1 must be recognized in advance. Similarly, a correlation between a value of the control signal CON2, for example, a voltage, and the intensity of the second light L2 must be recognized in advance.

The correlation between a control signal and intensity of light can be held in advance as table information in the amplification control unit 10, for example. The amplification control unit 10 can appropriately refer to table information TAB, and provide the control signals CON1 and CON2 associated to the target intensity to the first optical amplification unit 11 and the second optical amplification unit 12, respectively.

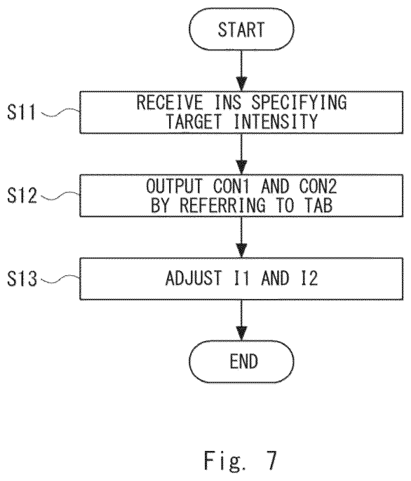

Next, a feedforward control operation according to the second example embodiment will be described. FIG. 7 illustrates a flowchart of feedforward control according to the second example embodiment.

### Step S11

The amplification control unit 10 receives an instruction INS specifying the target intensity of each of the first light L1 and the second light L2 from an external apparatus or the like. The instruction INS may be given, for example, from a signal processing unit 1003 illustrated in FIG. 1, or a not-illustrated control means provided in an optical module 100 or an optical transceiver 1000.

### Step S12

The amplification control unit 10 refers to the table information TAB held in advance, and outputs the control signals CON1 and CON2 associated to the specified target intensity.

### Step S13

The first optical amplification unit 11 sets an initial value of a current I1 in response to the control signal CON1. Similarly, the second optical amplification unit 12 sets an initial value of a current I2 in response to the control signal CON2.

In steps S11 to S13, the current I1 of the optical amplification unit 1 and the current I2 of the second optical amplification unit 12 are set based on the instruction INS without monitoring the intensity of each of the first light L1 and the second light L2. Thus, at this point of time, it is unclear whether the intensity of each of the first light L1 and the second light L2 becomes the target intensity.

Thus, by subsequently starting the feedback control described in the first example embodiment, the intensity of each of the first light L1 and the second light L2 can be set as a target value.

As described above, according to the present configuration, initial setting of intensity of each of the first light L1 and the second light L2 can be performed by feedforward control. Thereafter, the amplification control unit 10 performs feedback control of the intensity of each of the first light L1 and the second light L2, and thereby it is possible to control the intensity of each of the first light L1 and second light L2 with high accuracy.

### Other Example Embodiments

Note that, the present disclosure is not limited to the above-described example embodiments, and can be appropriately modified without departing from the spirit. For example, the configuration of the optical transceiver and the optical module described above is simplified for convenience of explanation, and it is needless to say that various other components may be included.

In the drawings referred to in the above example embodiments, transmission of a signal between components is represented by using an arrow, but this does not mean that the signal is transmitted only in one direction between two components, and bidirectional transmission of the signals can be made as necessary.

The configuration of the light source 6 described in the above-described example embodiment is merely an example. As long as the first light L1 and the second light L2 can be similarly output to the optical amplifier 1, the configuration of the light source may be another configuration.

While the disclosure has been particularly shown and described with reference to embodiments thereof, the disclosure is not limited to these embodiments. It will be understood by those of ordinary skill in the art that various changes in form and details may be made therein without departing from the spirit and scope of the present disclosure as defined by the claims.

What is claimed is:

1. An optical module comprising:
an optical amplifier configured to modulate first light having a first wavelength with a first modulation signal having a first frequency and amplify the first light, and modulate second light having a second wavelength different from the first wavelength with a second modulation signal having a second frequency different from the first frequency and amplify the second light;
a splitter configured to split the first light and the second light being output from the optical amplifier;
a light reception unit configured to receive the first light and the second light being split by the splitter, and output an electric signal indicating intensity of light acquired by adding the received first light and the received second light;
an intensity detection unit configured to extract a first component having the first frequency being included in the electric signal and a second component having the second frequency being included in the electric signal, and detect amplitude of the first component and amplitude of the second component; and
an amplification control unit configured to monitor intensity of the first light, based on amplitude of the first component, monitor intensity of the second light, based on amplitude of the second component, and control amplification of each of the first light and the second light in the optical amplifier, based on a monitoring result.

2. The optical module according to claim 1, wherein the amplification control unit controls the optical amplifier in such a way that amplitude of the first component and amplitude of the second component become constant.

3. The optical module according to claim 1, wherein the amplification control unit performs initial setting of amplification of each of the first light and the second light in the optical amplifier, based on information held in advance.

4. The optical module according to claim 1, wherein the amplification control unit
controls amplification of the first light in the optical amplifier in such a way that intensity of the first light falls within a first range, and
controls amplification of the second light in the optical amplifier in such a way that intensity of the second light falls within a second range.

5. An optical transceiver comprising:
a receiver configured to receive a received first wavelength multiplexed optical signal by interfering with first light having a first wavelength, and output a data signal acquired by demodulating the received signal;
a transmitter configured to modulate second light having a second wavelength different from the first wavelength in response to the data signal, and multiplex the modulated optical signal into a second wavelength multiplexed optical signal and output the multiplexed signal;
a signal processing unit configured to transfer the data signal being output from the receiver to the transmitter; and
an optical module configured to output the first light and the second light,
wherein the optical module includes
an optical amplifier configured to modulate the first light with a first modulation signal having a first frequency and amplify the first light, and modulate the second light with a second modulation signal having a second frequency different from the first frequency and amplify the second light,
a splitter configured to split the first light and the second light being output from the optical amplifier,
a light reception unit configured to receive the first light and the second light being split by the splitter, and output an electric signal indicating intensity of light acquired by adding the received first light and the received second light,
an intensity detection unit configured to extract a first component having the first frequency being included in the electrical signal and a second component having the second frequency being included in the electric signal, and detect amplitude of the first component and amplitude of the second component, and
an amplification control unit configured to monitor intensity of the first light, based on amplitude of the first component, monitor intensity of the second light, based on amplitude of the second component, and control amplification of each of the first light and the second light in the optical amplifier, based on a monitoring result.

6. A method of controlling intensity of light, comprising:
modulating first light having a first wavelength with a first modulation signal having a first frequency and amplifying the first light, and modulating second light having a second wavelength different from the first wavelength with a second modulation signal having a second frequency different from the first frequency and amplifying the second light;
splitting the first light and the second light being modulated and amplified;
receiving the first light and the second light being split, and outputting an electric signal indicating intensity of light acquired by adding the received first light and the received second light;
extracting a first component having the first frequency being included in the electric signal and a second component having the second frequency being included in the electric signal, and detecting amplitude of the first component and amplitude of the second component; and
monitoring intensity of the first light, based on amplitude of the first component, monitoring intensity of the second light, based on amplitude of the second component, and controlling amplification of each of the first light and the second light, based on a monitoring result.
